(19) United States
(12) Patent Application Publication
(10) Pub. No.: US 2026/0255881 A1
(43) Pub. Date: Aug. 27, 2026

(54) PIEZOELECTRIC ACTUATOR AND CAMERA MODULE INCLUDING PIEZOELECTRIC ACTUATOR

(71) Applicant: Samsung Electro-Mechanics Co., Ltd., Suwon-si (KR)

(72) Inventors: Dooseub SHIN, Suwon-si (KR); Sanghyun JI, Suwon-si (KR); Chueljin PARK, Suwon-si (KR)

(73) Assignee: Samsung Electro-Mechanics Co., Ltd., Suwon-si (KR)

(21) Appl. No.: 19/254,447

(22) Filed: Jun. 30, 2025

(30) Foreign Application Priority Data
Feb. 26, 2025 (KR) 10-2025-0025167

(51) Int. Cl. H10N 30/88; G03B 3/10; G03B 17/12

(52) U.S. Cl. CPC H10N 30/88; G03B 3/10; G03B 17/12

(57) ABSTRACT

A camera module includes a housing having an internal space, a carrier disposed in the internal space and accommodating a lens barrel having a lens mounted therein, and a piezoelectric actuator disposed in the housing, supporting the carrier, and configured to apply a driving force to the carrier in an optical axis direction, wherein the piezoelectric actuator includes a driving rod extending in the optical axis direction and supporting the carrier, a bracket including an upper frame comprising a supporting surface supporting one end of the driving rod, a lower frame comprising at least a pair of holding surfaces facing each other in a direction crossing the supporting surface and spaced apart from each other, and a middle frame connecting the upper frame and the lower frame to each other, and a piezoelectric element fixed between the pair of holding surfaces and spaced apart from the upper frame.

### CROSS-REFERENCE TO RELATED APPLICATIONS

This application claims the benefit under 35 USC 119(a) of Korean Patent Application No. 10-2025-0025167 filed on Feb. 26, 2025, the entire disclosures of which are incorporated herein by reference for all purposes.

### BACKGROUND

### 1. Field

This disclosure relates to a piezoelectric actuator and a camera module including a piezoelectric actuator.

### 2. Description of Background

Camera modules are typically installed in various electronic devices such as smartphones, automobiles, and smart appliances, serving to provide photos and videos. Although the image quality may be somewhat inferior to that of general digital cameras, they are built into most smartphones due to their excellent portability and accessibility. Camera modules include various functions such as auto focus (AF), optical image stabilization (OIS), aperture control (IRIS), and optical zoom, enabling high-quality photo and video capture.

To implement these functions, actuators that precisely control moving parts such as the lens unit are essential. Representative types include voice coil motors (VCM), piezoelectric actuators, electromagnetic actuators, and electrostatic actuators, each differing in driving principles and characteristics. For example, the VCM method operates using magnetic force, while piezoelectric actuators work on the principle of inducing minute deformation by applying an electric field.

With the advancement of camera modules, demands for miniaturization, low power consumption, and high output of actuators are increasing. Accordingly, next-generation actuator technologies that complement the disadvantages of existing methods while providing new functions are continuously being researched and developed, and various attempts are being made to find more efficient and stable driving methods.

### SUMMARY

This Summary is provided to introduce a selection of concepts in simplified form that are further described below in the Detailed Description. This Summary is not intended to identify key features or essential features of the claimed subject matter, nor is it intended to be used as an aid in determining the scope of the claimed subject matter.

In one general aspect, a camera module includes a housing having an internal space; a carrier disposed in the internal space of the housing and accommodating a lens barrel having a lens mounted therein; and a piezoelectric actuator disposed in the housing, supporting the carrier, and configured to apply a driving force to the carrier in an optical axis direction, wherein the piezoelectric actuator includes a driving rod extending in the optical axis direction and supporting the carrier; a bracket including an upper frame including a supporting surface supporting one end of the driving rod, a lower frame including at least a pair of holding surfaces facing each other in a direction crossing the supporting surface and spaced apart from each other, and a middle frame connecting the upper frame and the lower frame to each other; and a piezoelectric element fixed between the pair of holding surfaces and spaced apart from the upper frame.

One side surface of the driving rod may contact one corner of the carrier.

The camera module may further include a carrier preload spring fixed to the carrier; and a housing preload spring fixed to the housing, wherein the driving rod may be interposed between the carrier preload spring and the housing preload spring so that the driving rod is pressed between the carrier preload spring and the housing preload spring.

A portion of the carrier preload spring may be inserted into the carrier, and another portion of the carrier preload spring may protrude from the carrier and contact the driving rod.

Opposite ends of the housing preload spring may be fixed to adjacent side walls of the housing, and a middle portion of the housing preload spring may contact the driving rod.

The bracket may be fixed to the housing.

The camera module may further include a rolling member disposed between the carrier and the housing, wherein the driving rod and the rolling member may be disposed at opposite corners of the carrier.

The piezoelectric element may be fixed in contact with the holding surfaces of the lower frame of the bracket.

A cavity may be formed between the piezoelectric element and the upper frame as a result of the piezoelectric element being spaced apart from the upper frame.

The middle frame may extend downward from opposite edges of the upper frame.

The middle frame may include an inclined surface extending from the upper frame and connecting to the lower frame.

A width of the piezoelectric element may be greater than a cross-sectional diameter of the driving rod.

The middle frame may include a first bracket hole formed as a through opening in the middle frame.

The lower frame may include a second bracket hole formed as a through opening in the lower frame.

In another general aspect, a piezoelectric actuator includes a driving rod extending in one direction; a bracket including an upper frame including a supporting surface supporting one end of the driving rod, a lower frame including at least a pair of holding surfaces facing each other in a direction crossing the supporting surface and spaced apart from each other, and a middle frame connecting the upper frame and the lower frame to each other; and a piezoelectric element fixed between the pair of holding surfaces of the lower frame of the brackets and spaced apart from the upper frame.

The piezoelectric element may be fixed in contact with the holding surfaces of the lower frame of the brackets.

A cavity may be formed between the piezoelectric element and the upper frame as a result of the piezoelectric element being spaced apart from the upper frame.

The middle frame may extend downward from opposite edges of the upper frame.

The middle frame may include an inclined surface extending from the upper frame and connecting to the lower frame.

A width of the piezoelectric element may be greater than a cross-sectional diameter of the driving rod.

The middle frame may include a first bracket hole formed as a through opening in the middle frame.

The lower frame may include a second bracket hole formed as a through opening in the lower frame.

In another general aspect, a piezoelectric actuator includes a driving rod; a bracket including a supporting surface supporting one end of the driving rod so that the driving rod extends in a direction perpendicular to the mounting surface, and a pair of holding surfaces facing each other in a direction parallel to the supporting surface; and a piezoelectric element fixed between the pair of holding surfaces, wherein the piezoelectric element is configured to bend away from the supporting surface in response to a voltage having a first polarity applied to the piezoelectric element, and bend toward the supporting surface in response to a voltage having a second polarity opposite to the first polarity applied to the piezoelectric element, and the mounting bracket is configured to be deformed by the piezoelectric element bending away from the supporting surface so that the supporting surface moves away from the piezoelectric element, thereby moving the driving rod in a first direction, and be deformed by the piezoelectric element bending toward the supporting surface so that the supporting surface moves toward the piezoelectric element, thereby moving the driving rod in a second direction opposite to the first direction.

The mounting bracket may include an upper frame including the supporting surface; a lower frame including the pair of holding surfaces; and a middle frame connecting the upper frame and the lower frame to each other.

A width of the lower frame in the direction parallel to the supporting surface may be greater than a width of the upper frame in the direction parallel to the supporting surface, and a width of the middle frame in the direction parallel to the supporting surface increases from the upper frame toward the lower frame.

The middle frame may include a bracket hole formed as a through opening in the middle frame and extending in the direction parallel to the supporting surface.

Other features and aspects will be apparent from the following detailed description, the drawings, and the claims.

### BRIEF DESCRIPTION OF DRAWINGS

FIG. 1 is a schematic diagram illustrating a piezoelectric actuator to explain the operating principle of a SIDM (Smooth Impact Drive Mechanism) piezoelectric actuator.

FIG. 2 is a graph illustrating applied voltage waveforms for driving the SIDM piezoelectric actuator.

FIG. 3 is a perspective view illustrating a camera module according to an embodiment.

FIG. 4 is an exploded perspective view illustrating the camera module shown in FIG. 3.

FIG. 5 is a plan view illustrating the camera module shown in FIG. 3 with the cover removed.

FIG. 6 is a side view illustrating the camera module shown in FIG. 3 with the cover removed.

FIG. 7 is a cross-sectional view taken along the line VII-VII′ in FIG. 5.

FIG. 8 is a perspective view illustrating a piezoelectric actuator according to an embodiment.

FIG. 9 is a side view illustrating the piezoelectric actuator shown in FIG. 8.

FIG. 10 is a diagram illustrating a simulated operational shape of the piezoelectric actuator shown in FIG. 8.

FIG. 11 is a perspective view illustrating a piezoelectric actuator according to another embodiment.

FIG. 12 is a perspective view illustrating a bracket of the piezoelectric actuator shown in FIG. 11.

FIG. 13 is a perspective view illustrating a piezoelectric actuator according to another embodiment.

FIG. 14 is a graph showing changes in a resonant frequency and a driving displacement according to a height of a cavity of the piezoelectric actuator shown in FIG. 8.

FIG. 15 is a graph showing changes in the resonant frequency and the driving displacement according to a thickness of a bracket of the piezoelectric actuator shown in FIG. 8.

FIG. 16 is a graph showing changes in a resonant frequency and a driving displacement according to a horizontal length of a first bracket hole of the piezoelectric actuator shown in FIG. 11.

FIG. 17 is a graph showing changes in the resonant frequency and the displacement according to a vertical length of the first bracket hole of the piezoelectric actuator shown in FIG. 11.

Throughout the drawings and the detailed description, the same reference numerals refer to the same elements. The drawings may not be to scale, and the relative sizes, proportions, and depictions of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of functions and constructions that would be well known to one of ordinary skill in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

The use of the term “may” with respect to an example or embodiment, e.g., as to what an example or embodiment may include or implement, means that at least one example or embodiment exists in which such a feature is included or implemented, while all examples and embodiments are not necessarily limited thereto.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween, or the elements may be physically connected as well as electrically connected, or the elements may be integral despite being referred to by different names according to position or function. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as illustrated in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated by 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Also, throughout the specification, “plan view” means that the subject part is viewed from above, and “cross-sectional view” means that a cross-section of the subject part cut vertically is viewed from the side.

When a voltage is applied to a piezoelectric element, the piezoelectric element undergoes mechanical deformation such as expansion and contraction, with the characteristic that the driving displacement is very small, at the level of a few micrometers (μm). Various methods are used to overcome this small driving displacement and obtain a larger movement displacement, notably the inchworm method, the ultrasonic method, and methods using inertial force. Among these, the SIDM (Smooth Impact Drive Mechanism) method, which uses inertial force, has the advantage of being suitable for application to camera modules as it has a simple structure and may configure a system with just one piezoelectric element.

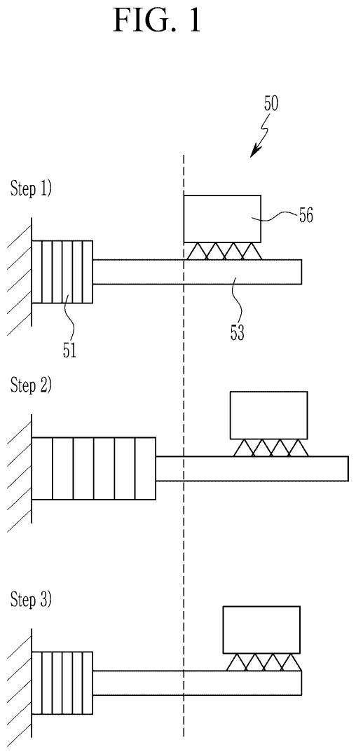

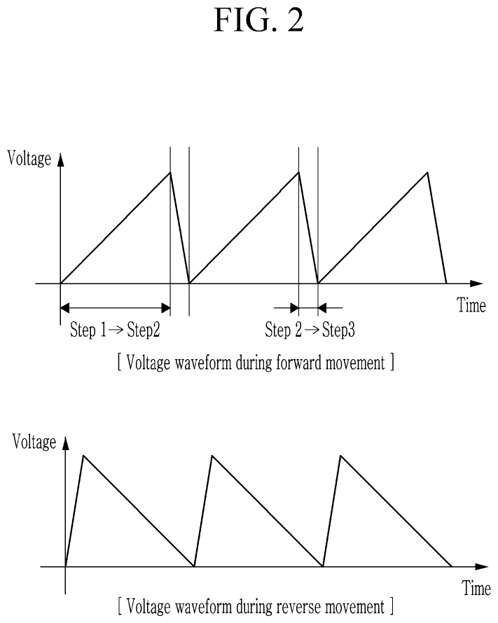

FIG. 1 is a schematic diagram illustrating a piezoelectric actuator to explain the operating principle of an SIDM piezoelectric actuator, and FIG. 2 is a graph illustrating applied voltage waveforms for driving the SIDM piezoelectric actuator.

Referring to FIG. 1, a SIDM piezoelectric actuator 50 may include three components: a piezoelectric element 51, a rod 53, and a slider 56. Here, the piezoelectric element 51 is the main component that converts electrical energy into mechanical displacement, and is firmly bonded to the rod 53 with an adhesive. Generally, one surface of the piezoelectric element 51 is fixed, and the slider 56, which is the moving part, is placed on the rod 53 and fixed by applying a preload to the slider 56. At this time, the slider 56 is connected to the rod 53 by friction, and the piezoelectric element 51 has the characteristic of repeatedly contracting and expanding according to a voltage difference between both ends, utilizing the principle that the slider 56 moves accordingly.

The driving process of the SIDM driving method is as follows. First, when the driving voltage applied to the piezoelectric element 51 is slowly increased, the piezoelectric element 51 gradually stretches, and during this process, the slider 56 moves together with the rod 53 due to friction between the slider 56 and the rod 53 (Step 1→Step 2). On the other hand, when the driving voltage is rapidly reduced to quickly contract the piezoelectric element 51, the slider 56 remains in its position as the inertial force becomes greater than the frictional force, causing the rod 53 to slide through the slider 56 (Step 2→Step 3). By repeating this driving of gradual expansion and rapid contraction, the slider 56 can continuously travel a long distance.

The voltage waveform when the slider 56 moves in the forward direction is shown in the upper graph of FIG. 2. Conversely, when the operations of rapidly expanding and slowly contracting the piezoelectric element 51 are repeated, the slider 56 is driven in the reverse direction, which is the application of the forward driving principle in the opposite manner. The voltage waveform at this time is shown in the lower graph of FIG. 2, showing a waveform opposite to that of the forward driving.

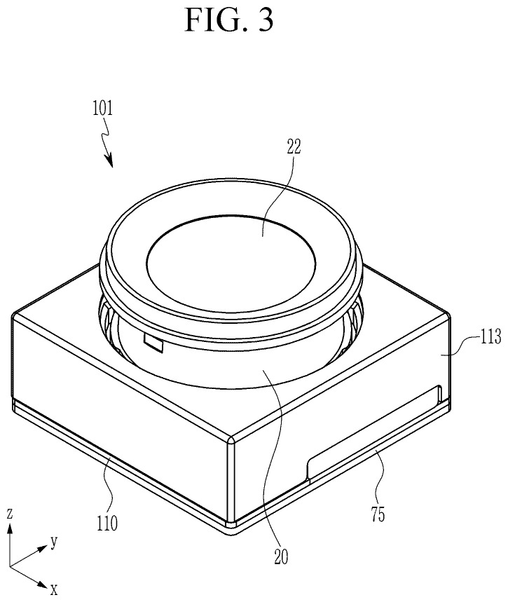

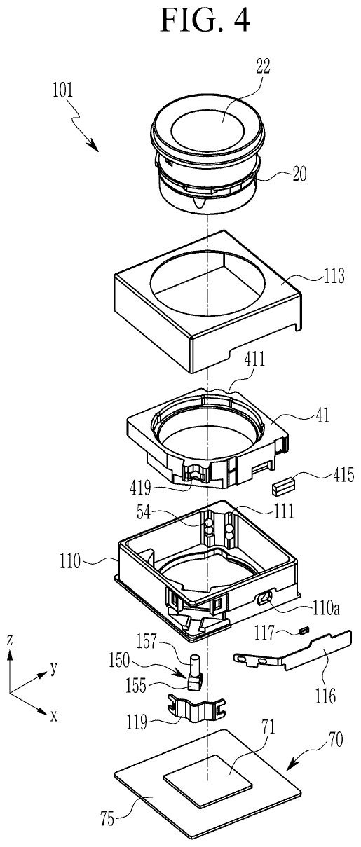

FIG. 3 is a perspective view illustrating a camera module according to an embodiment, and FIG. 4 is an exploded perspective view illustrating the camera module shown in FIG. 3.

Referring to FIGS. 3 and 4, a camera module 101 according to this embodiment may include a lens barrel 20 for capturing a subject, a carrier 41 supporting the lens barrel 20, an image sensor unit 70 that converts optical signals into electrical signals, a housing 110 accommodating these components, and a piezoelectric actuator 150 implementing an auto-focus function.

The lens barrel 20 has a hollow cylindrical shape and may accommodate one or multiple lenses 22 inside. Multiple lenses 22 may be aligned in a row along the optical axis and mounted in the lens barrel 20, and each lens 22 may have the same or different optical characteristics such as a refractive index, a radius of curvature, a thickness, and other characteristics according to design requirements. The optical axis may be set as the center axis of the lens 22 and may coincide with a z-axis direction, and an x-axis and a y-axis, which are perpendicular to each other, may be set in a direction perpendicular to the optical axis and the z-axis. Through this coordinate system setting, the position and movement direction of each component of the camera module 101 may be clearly defined.

The carrier 41 is a structure for stably supporting the lens barrel 20, and has a central aperture to precisely accommodate the lens barrel 20. The carrier 41 combined with the lens barrel 20 may be accommodated in the internal space of the housing 110, and the housing 110 may have a box shape with four corners, with the top and bottom open. The central aperture of the carrier 41 and a central aperture of the housing 110 may be precisely aligned in the optical axis direction to secure the alignment precision of the optical system.

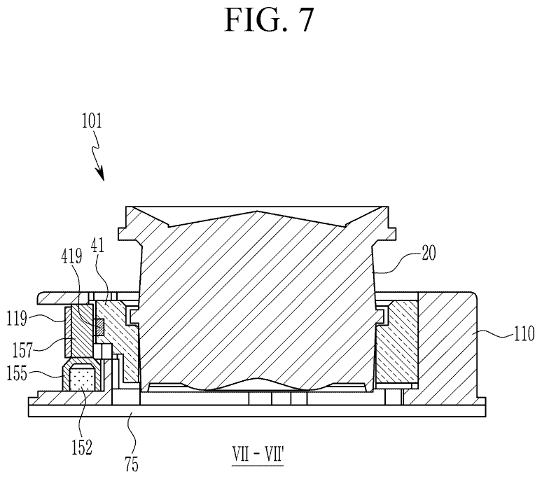

The piezoelectric actuator 150 may be disposed inside any one of the four corners of the housing 110. The piezoelectric actuator 150 may be positioned in the space between an outer corner of the carrier 41 and an inner corner of the housing 110, and may include a piezoelectric element 152 (not shown in FIGS. 3 and 4, but see FIG. 7) and a driving rod 157 mechanically connected through a bracket 155. The piezoelectric element 152 is fixed to the corner of the housing 110, and the driving rod 157 may be supported by the carrier 41.

The driving rod 157 has a cylindrical shape and its side surface may contact a carrier preload spring 419 and a housing preload spring 119. For example, one side of the cylindrical side surface of the driving rod 157 contacts the carrier preload spring 419 provided on the outer corner of the carrier 41, and the other side of the cylindrical side surface of the driving rod 157 contacts the housing preload spring 119 fixed to the housing 110. The preload springs may have a plate spring form and may be made of a durable metal material such as stainless steel (SUS), and may apply an appropriate preload to the driving rod 157 to enable a stable driving force transmission.

This piezoelectric actuator 150 may perform the function of an auto focus (AF) driving unit that moves the carrier 41 in the optical axis direction with respect to the housing 110. The position of the piezoelectric actuator 150 may be selectively placed in any one of the four corners of the housing 110, and accordingly, a position of a rolling member 54 may be placed in the diagonally opposite corner of the corner where the piezoelectric actuator 150 is installed.

The rolling member 54 may be placed between the carrier 41 and the housing 110 to reduce friction between them when the carrier 41 is moved. The rolling member 54 may be placed at the diagonally opposite corner of the piezoelectric actuator 150. The rolling member 54 has a ball form with multiple balls placed on both sides of the respective corner of the carrier 41, which may minimize friction occurring during the movement of the carrier 41 and enable smooth movement of the carrier 41.

A sensing magnet 415 may be placed on the outside of one side of the carrier 41. A flexible circuit board 116 is placed on the outside of one side of the housing 110, and a sensor 117 may be placed on the flexible circuit board 116 at a position corresponding to the sensing magnet 415. A through hole 110a is formed in the side wall of the housing 110 to correspond to the sensor 117, and through this through hole 110a, the sensor 117 and the sensing magnet 415 may be aligned to face each other. The sensor 117 may detect the position of the lens barrel 20 in the optical axis direction, and the flexible circuit board 116 may be configured to supply power to the sensor 117.

The image sensor unit 70 may be placed at the bottom of the housing 110. The image sensor unit 70 is a device that converts light incident through the lens barrel 20 into electrical signals. The image sensor unit 70 may include an image sensor 71 and a circuit board 75 connected to it, and may further include an infrared filter (not shown). The infrared filter serves to block light in the infrared region from the light incident through the lens barrel 20.

A cover 113 covers the outer surface of the housing 110, protecting the internal components from external impacts or foreign substances. The cover 113 is made of a metal material and may effectively shield electromagnetic waves generated in the camera module 101 so that they do not affect surrounding electronic components in a portable electronic device. This minimizes electromagnetic interference within the electronic device and ensures stable operation.

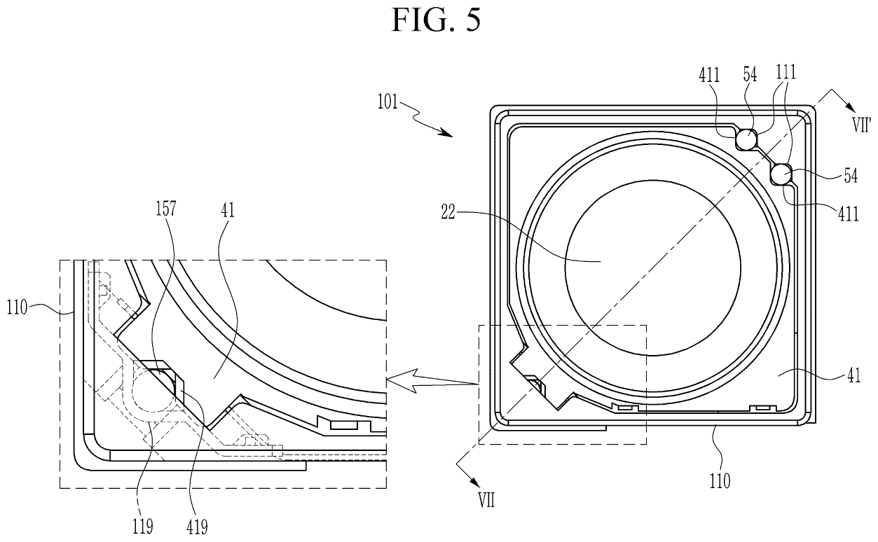

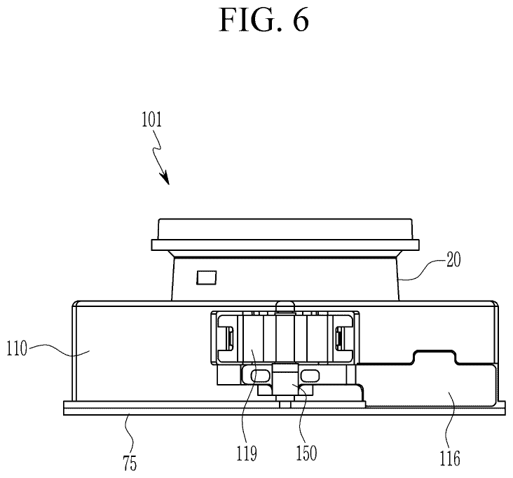

FIG. 5 is a plan view illustrating the camera module shown in FIG. 3 with the cover removed, FIG. 6 is a side view illustrating the camera module shown in FIG. 3 with the cover removed, and FIG. 7 is a cross-sectional view taken along line VII-VII′ in FIG. 5.

Referring to FIGS. 5 to 7, the driving rod 157 of the piezoelectric actuator 150 may be positioned in the space between the outer corner of the carrier 41 and the inner corner of the housing 110. The piezoelectric actuator 150 and the rolling member 54 may be positioned on diagonally opposite sides of the carrier 41, and through this diagonal arrangement, balanced support and stable movement of the carrier 41 may be possible.

The driving rod 157 may be fixed by its sides being pressed from both directions by the carrier preload spring 419 and the housing preload spring 119. The carrier preload spring 419 may be firmly fixed in place by being combined with the carrier 41 in an insert molding process, and a portion of it protrudes from one corner of the carrier 41 to contact the driving rod 157 and apply constant pressure. The housing preload spring 119 may be stably supported by having both ends fixed to adjacent side walls of the housing 110, and a middle portion exposed from the housing 110 contacts and presses the driving rod 157.

The carrier preload spring 419 and the housing preload spring 119 may precisely maintain a friction with the driving rod 157 positioned between them by applying constant pressure in directions opposing each other. Specifically, the carrier preload spring 419 may be formed so that two parts contacting the driving rod 157 face each other at a predetermined angle, and through this dual contact structure, the position of the driving rod 157 may be stably fixed. The housing preload spring 119 may also provide uniform support force by having its exposed middle portion curved at a predetermined angle to contact the side of the driving rod 157 at at least two points, or along a portion of a circumference of the side of the driving rod 157.

The rolling member 54 has a ball form and may be symmetrically arranged based on the diagonal of the carrier 41 or the housing 110. Guide grooves 411 and 111 extending in the optical axis may be concavely formed in the outer surface of the carrier 41 and the inner surface of the housing 110, respectively, to accommodate the rolling member 54 and guide it in the optical axis direction. The guide grooves 411 and 111 face each other, forming an accommodation space in which the rolling member 54 may be interposed between them, thus precisely guiding the linear motion of the carrier 41 in the optical axis direction.

The driving rod 157 of the piezoelectric actuator 150 may be firmly attached and fixed on the bracket 155. The bracket 155 holds the piezoelectric element 152 and is fixed inside the housing 110 to stably support the piezoelectric actuator 150. When a voltage is applied to the piezoelectric element 152, its structure may be deformed, which induces a change in the form of the bracket 155, causing the driving rod 157 to rise or fall in the optical axis direction. The driving rod 157 is held in contact with the carrier 41 by the carrier preload spring 419 and the housing preload spring 119, thereby supporting the carrier 41 and implementing a precise auto focus (AF) function of the carrier 410.

The piezoelectric actuator 150 of the camera module 101 according to this embodiment may provide various advantages compared to the conventional voice coil motor (VCM) method. Specifically, the conventional voice coil motor may occupy a considerable volume by being positioned along one side of a camera module. In contrast, the piezoelectric actuator 150 may be placed at a corner of the camera module 101, reducing the total volume of the camera module 101 by about 8%. Additionally, the height of the piezoelectric actuator 150 may be smaller than the height of the voice coil motor, reducing the overall height of the camera module 101 by about 12%.

In addition, the piezoelectric actuator 150 has a reduced resonant frequency and an improved driving displacement, which may improve the movement speed and precision of the carrier 41. As a number of layers of the piezoelectric element 152 decreases, a capacitance of the piezoelectric element 152 decreases, reducing manufacturing costs, and especially, malfunction and noise generation due to interference between different vibration frequencies are minimized, providing stable driving characteristics. Through these structural features, both miniaturization and high performance of the camera module 101 may be simultaneously realized.

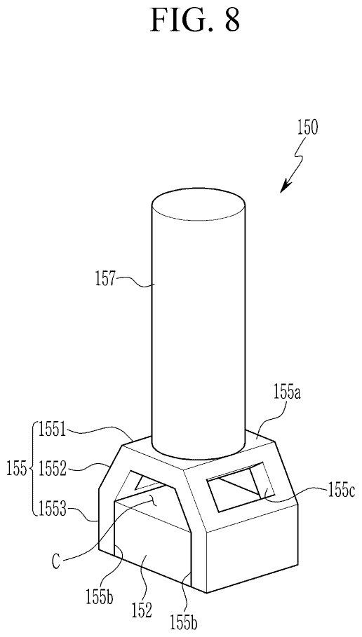

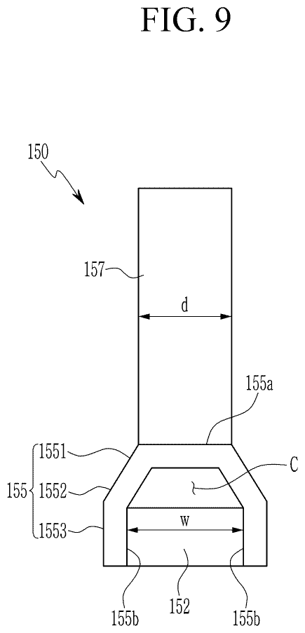

FIG. 8 is a perspective view illustrating a piezoelectric actuator according to an embodiment, and FIG. 9 is a side view illustrating the piezoelectric actuator shown in FIG. 8.

Referring to FIGS. 8 and 9, the piezoelectric actuator 150 may be composed of a driving rod 157, a bracket 155, and a piezoelectric element 152. The bracket 155, which is the main structure of the piezoelectric actuator 150, is formed as an integral structure to ensure structural stability, and may include an upper frame 1551, a middle frame 1552, and a lower frame 1553. Each frame may have different functional structures suitable for the driving characteristics of the piezoelectric actuator 150.

The upper frame 1551 of the bracket 155 may have a supporting surface 155a that stably supports one end of the driving rod 157. The lower frame 1553 includes at least a pair of holding surfaces 155b facing each other in a direction crossing the supporting surface 155a and spaced apart from each other, firmly fixing the piezoelectric element 152. The middle frame 1552 structurally connects the upper frame 1551 and the lower frame 1553, securing the overall rigidity and stability of the bracket 155.

The piezoelectric element 152 may be firmly fixed between the pair of holding surfaces 155b and may be spaced apart from the upper frame 1551 by a predetermined distance, forming an empty space called a cavity C between them. This cavity C structure may facilitate the deformation of the piezoelectric element 152, improving an driving efficiency. The piezoelectric element 152 may be fixed in stable contact with the holding surfaces 155b, and for efficient driving force transmission, a width w of the piezoelectric element 152 may be designed to be larger than a cross-sectional diameter d of the driving rod 157.

The middle frame 1552 may extend downward from the opposing edges of the upper frame 1551, providing structural rigidity. Additionally, the middle frame 1552 comprises an inclined surface extending from the upper frame 1551 and connecting to the lower frame 1553, effectively dispersing stress caused by the deformation of the piezoelectric element 152. This inclined surface structure may prevent stress concentration occurring during the driving of the piezoelectric element 152 and improve the durability of the bracket 155.

The middle frame 1552 may have a first bracket hole 155c formed as a through opening. The first bracket hole 155c may be symmetrically formed on both sides of the lower frame 1553. The first bracket hole 155c may serve to reduce the resonant frequency of the piezoelectric actuator 150 and increase the driving displacement. For example, the first bracket hole 155c may be a rectangular through opening, maintaining structural rigidity while simultaneously improving resonance characteristics. However, the shape of the first bracket hole 155c is not necessarily limited to a rectangular shape, and any shape that can reduce the resonant frequency and increase the displacement may be used.

Regarding the material of the bracket 155, the bracket 155 may be made of a metal with an excellent durability, and for improved vibration characteristics, a phosphor bronze series alloy with a high density and a low Young's modulus may be used. These material characteristics may improve the responsiveness of the bracket 155 to the deformation of the piezoelectric element 152, enhancing the driving efficiency of the piezoelectric actuator 150. Additionally, the excellent durability of the phosphor bronze series alloy may prevent deformation or fatigue failure of the bracket 155 even with repeated driving.

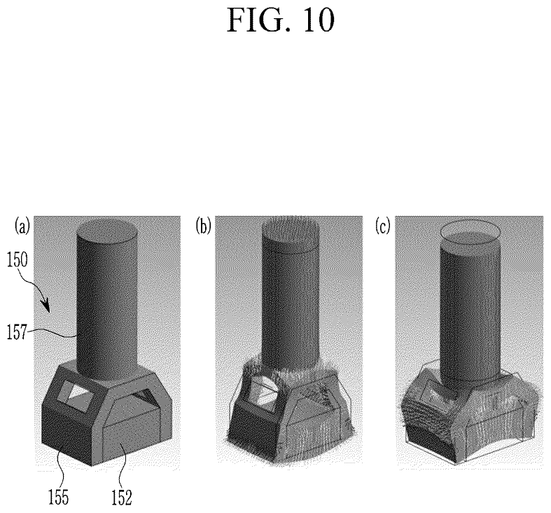

FIG. 10 is a diagram illustrating a simulated operational shape of the piezoelectric actuator shown in FIG. 8. Section (a) of FIG. 10 shows the initial state before operation, section (b) of FIG. 10 shows the state when a positive voltage is applied, and section (c) of FIG. 10 shows the state when a negative voltage is applied.

Referring to FIG. 10, the piezoelectric actuator 150 may be driven in different directions depending on the polarity of the voltage applied to the piezoelectric element 152. A sinusoidal voltage may be applied to the piezoelectric element 152, and the direction of deformation of the piezoelectric element 152 is determined according to the polarity of this voltage, controlling the movement direction of the driving rod 157.

The initial state of the piezoelectric actuator 150 may maintain a neutral state where the piezoelectric element 152 is not deformed, as shown in section (a) of FIG. 10. From this initial state, when a positive (+) voltage is applied to the piezoelectric element 152, the piezoelectric element 152 may be bent and deformed in the −z direction, as shown in section (b) of FIG. 10. At this time, due to the bending deformation of the piezoelectric element 152, the lower frame 1553 of the bracket 155 coupled with it may receive a compressive force in the inward direction. This structural deformation of the bracket 155 may raise the driving rod 157 in the +z direction.

Conversely, when a negative (−) voltage is applied to the piezoelectric element 152, the piezoelectric element 152 may be bent and deformed in the +z direction, as shown in section (c) of FIG. 10. At this time, the deformation of the piezoelectric element 152 may stretch the lower frame 1553 of the bracket 155 in an outward direction. This structural deformation of the bracket 155 may lower the driving rod 157 in the −z direction.

Through this structural mechanism, the bending deformation motion of the piezoelectric element 152 may be effectively converted into an up and down linear motion of the driving rod 157. In particular, by controlling the period of the sinusoidal voltage applied to the piezoelectric element 152, an up and down movement period of the driving rod 157 may be precisely controlled. This enables precise position control necessary for the auto-focus function of the camera module.

Considering the relationship between the structure of the bracket 155 and the deformation of the piezoelectric element 152, when a voltage is applied, the bending deformation of the piezoelectric element 152 may be effectively transmitted to the driving rod 157 through the lower frame 1553 of the bracket 155. Through this structural connection, the deformation amount of the piezoelectric element 152 may be amplified and transmitted as the displacement of the driving rod 157, which may improve the driving efficiency of the piezoelectric actuator 150 and reduce power consumption. This driving method using the bending deformation of the piezoelectric element 152 may provide a faster response characteristics and a higher positional precision compared to the conventional voice coil motor method.

This driving mechanism is designed to enable stable operation even with repeated deformation of the piezoelectric element 152, providing a reliable auto-focus function even during long-term use. In particular, the structural design and material characteristics of the bracket 155 are selected to maintain durability even under repeated stress, which may contribute to improving the lifespan and reliability of the camera module.

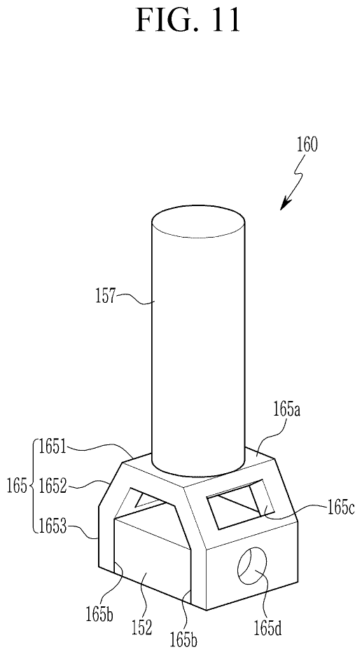

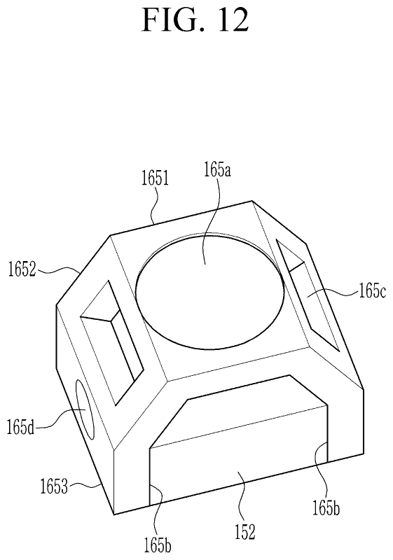

FIG. 11 is a perspective view illustrating a piezoelectric actuator according to another embodiment, and FIG. 12 is a perspective view illustrating a bracket of the piezoelectric actuator shown in FIG. 11.

Referring to FIG. 11, a piezoelectric actuator 160 according to this embodiment may be composed of a driving rod 157, a bracket 165, and a piezoelectric element 152. The bracket 165 may be formed as an integral structure to secure structural stability, and may include an upper frame 1651, a middle frame 1652, and a lower frame 1653. Each frame may have different functional structures suitable for the driving characteristics of the piezoelectric actuator 160.

A first bracket hole 165c in the form of a through opening may be formed in the middle frame 1652. The first bracket hole 165c may be symmetrically formed on both sides of the lower frame 1653. The first bracket hole 165c may perform a role of reducing a weight of the bracket 165, and may make the bracket 165 more flexibly deformable when the piezoelectric element 152 undergoes bending deformation. This structural feature may enable the driving force of the piezoelectric element 152 to be effectively transmitted to the driving rod 157 through the bracket 165.

A second bracket hole 165d for firm bonding with the piezoelectric element 152 may be formed in the lower frame 1653. The second bracket hole 165d may be symmetrically formed on both sides of the lower frame 1653 to provide a space where adhesive between the piezoelectric element 152 and the bracket 165 may be uniformly applied. Uniform application of adhesive may allow the driving force of the piezoelectric element 152 to be effectively transmitted to the bracket 165. Additionally, the second bracket hole 165d is formed as a through opening, contributing to an overall weight reduction of the bracket 165, which may improve the driving efficiency of the piezoelectric actuator 160.

Referring to FIG. 12, the upper frame 1651 may include a supporting surface 165a for stable coupling of the driving rod 157. A precisely machined groove may be formed in the supporting surface 165a so that the driving rod 157 may be placed at an exact position. This groove structure may prevent the driving rod 157 from disengaging from the bracket 165 and may perform a role of effectively transmitting the driving force from the bending deformation of the piezoelectric element 152 to the driving rod 157.

The lower frame 1653 includes at least a pair of holding surfaces 165b facing each other in a direction crossing the supporting surface 165a and spaced apart from each other, firmly fixing the piezoelectric element 152. The middle frame 1652 structurally connects the upper frame 1651 and the lower frame 1653, securing the overall rigidity and stability of the bracket 165. The piezoelectric element 152 may be firmly fixed between the pair of holding surfaces 165b by the adhesive applied between the piezoelectric element 152 and the bracket 165.

Through this integrated structure and the specialized configuration of each frame, stable bonding between the piezoelectric element 152 and the bracket 165 is possible, accurate positioning and driving force transmission of the driving rod 157 is possible, and at the same time, an improved driving efficiency through weight reduction may be achieved. In particular, the precise coupling structure between each component may ensure reliable operation of the piezoelectric actuator 160.

By securing space for an applying an adhesive between the piezoelectric element 152 and the bracket 165 through the second bracket hole 165d, an adhesion area increases, improving a bonding strength. This robust bonding may enable the driving force of the piezoelectric element 152 to be transmitted to the bracket 165 without loss. Additionally, the precise coupling structure between the driving rod 157 and the supporting surface 165a may maintain stable operational characteristics even in a repetitive driving environment.

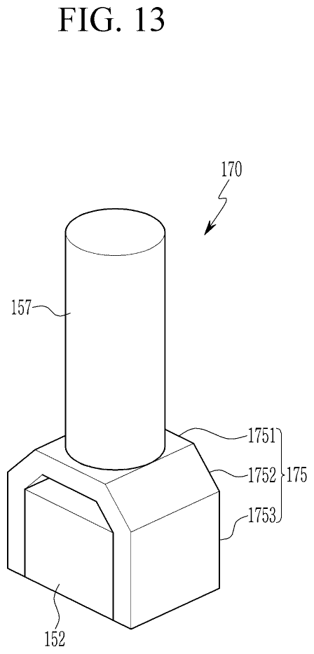

FIG. 13 is a perspective view illustrating a piezoelectric actuator according to another embodiment.

Referring to FIG. 13, a piezoelectric actuator 170 according to this embodiment may be composed of a driving rod 157, a bracket 175, and a piezoelectric element 152. The bracket 175 may be formed as an integral structure made of a single metal material, securing structural stability, and may include an upper frame 1751, a middle frame 1752, and a lower frame 1753. Each frame may have different functional structures suitable for the driving characteristics of the piezoelectric actuator 170.

The bracket 175 of the piezoelectric actuator 170 according to this embodiment may have different structural features from the bracket 165 of the embodiment shown in FIG. 11. Unlike the bracket 165 that includes the first bracket hole 165c and the second bracket hole 165d, the bracket 175 may not have any through openings. Specifically, the middle frame 1752 and the lower frame 1753 may all be formed without any openings.

This integral structure may increase the rigidity of the bracket 175, allowing for more effective transmission of the driving force from the piezoelectric element 152. Due to the structure without through openings, the bracket 175 may have an increased contact area with the piezoelectric element 152, improving a bonding strength, which may enable more stable transmission of the driving force from the bending deformation of the piezoelectric element 152 to the driving rod 157.

In addition, the integral structure of the bracket 175 without through openings may improve the durability of the piezoelectric actuator 170. Due to this structural feature, deformation or damage to the bracket 175 may be prevented even in a repetitive driving environment, and the bonding state with the piezoelectric element 152 may be maintained stably for a long period.

The metal material and integral structure of the bracket 175 may make it possible to transmit the driving force of the piezoelectric element 152 to the driving rod 157 without loss. This may improve the driving efficiency of the piezoelectric actuator 170 and contribute to implementing a stable auto-focus function.

### Simulation 1

To verify the resonant frequency and driving displacement characteristics, simulations were performed on the main design parameters of the piezoelectric actuator 150. The main design parameters include the height of the cavity C, the thickness of the bracket 155, and the horizontal and vertical lengths of the first bracket hole 155c. These design parameters may directly affect the driving performance of the piezoelectric actuator 150.

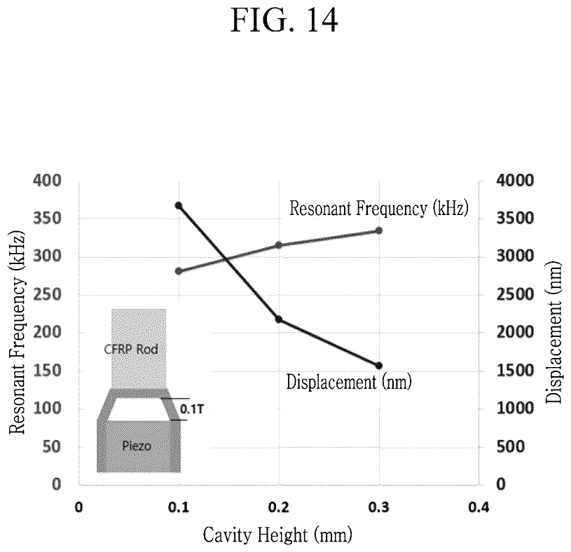

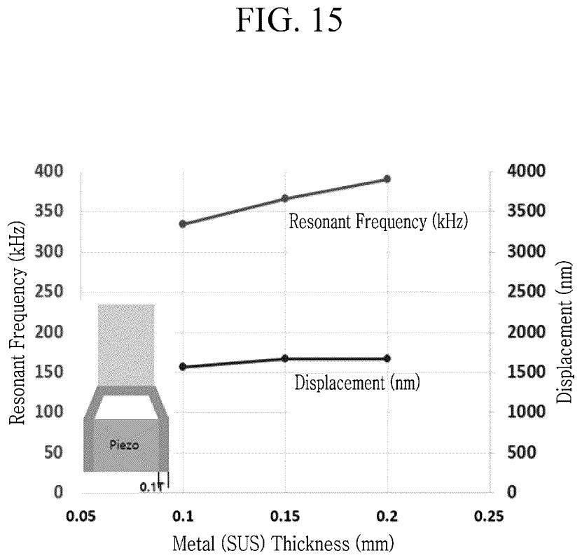

FIG. 14 is a graph showing changes in a resonant frequency and a driving displacement according to a height of a cavity of the piezoelectric actuator shown in FIG. 8, and FIG. 15 is a graph showing changes in the resonant frequency and the driving displacement according to a thickness of a bracket of the piezoelectric actuator shown in FIG. 8.

Referring to FIG. 14, for convenience of reference, the piezoelectric actuator is also illustrated, and the height of the cavity C is exemplarily shown as 0.1 T (0.1 mm). T represents a unit of thickness where 1 T equals 1 mm. In FIG. 14, a correlation between the height of the cavity C and the resonant frequency and the driving displacement may be observed. Specifically, as the height of the cavity C decreases, the driving displacement increases and the resonant frequency decreases. This indicates that the height of the cavity C affects the bending deformation characteristics of the piezoelectric element 152.

Referring to FIG. 15, for convenience of reference, the piezoelectric actuator is also illustrated, and the thickness of the bracket 155 (the metal (SUS) thickness) is exemplarily shown as 0.1 T (0.1 mm). In FIG. 15, a correlation between the thickness of the bracket 155 and the resonant frequency and the driving displacement may be observed. As the thickness of the bracket 155 decreases, the driving displacement does not undergo a significant change, but the resonant frequency increases. This indicates that the thickness of the bracket 155 directly affects the rigidity of the piezoelectric actuator 150.

Through these simulation results, it may be confirmed that the driving characteristics of the piezoelectric actuator 150 may be influenced by the height of the cavity C and the thickness of the bracket 155, and it is advantageous to apply a low cavity C height and a thin bracket 155 thickness.

### Simulation 2

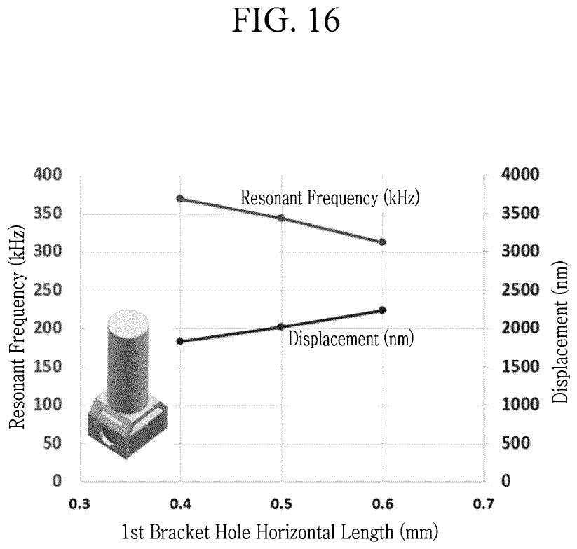

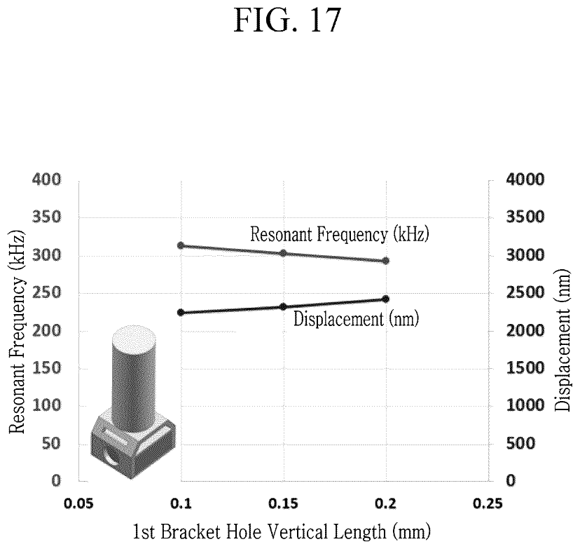

FIG. 16 is a graph showing changes in a resonant frequency and a driving displacement according to a horizontal length of the first bracket hole of the piezoelectric actuator shown in FIG. 11, and FIG. 17 is a graph showing changes in the resonant frequency and the driving displacement according to a vertical length of the first bracket hole of the piezoelectric actuator shown in FIG. 11.

Referring to FIGS. 16 and 17, a correlation between the size of the first bracket hole 165c formed in the bracket 165 shown in FIG. 11 and the resonant frequency and the driving displacement may be observed. Simulation results show that as the horizontal and vertical lengths of the first bracket hole 165c increase, the resonant frequency decreases and the driving displacement increases. This indicates that the size of the first bracket hole 165c directly affects the driving characteristics of the piezoelectric actuator 160.

In this embodiment, the dimensions of each design parameter may be set considering the stability of the manufacturing process. The thickness of the bracket 165 was formed as 0.2 T (0.2 mm), which is the minimum manufacturable thickness. While the driving characteristics may improve as the size of the first bracket hole 165c increases, there may be a constraint that a thickness of a border around the first bracket hole 165c decreases. Therefore, the size of the first bracket hole 165c was set to maintain a minimum thickness of 0.2 T (0.2 mm) for the top, bottom, left, and right borders of the first bracket hole 165c. Considering these design constraints, the height of the cavity C was set to a minimum value of 0.3 T (0.3 mm). By optimizing the dimensions of each design parameter in this way, both the driving performance and the manufacturing stability of the piezoelectric actuator 160 may be secured simultaneously.

### Simulation 3

Next, simulations were performed on various metal materials to analyze the effect of the material of the bracket 155 on the performance of the piezoelectric actuator 150 shown in FIG. 8. Specifically, stainless steel (SUS316), phosphor bronze (C5210), and beryllium copper (C1720) were each used as the material of the bracket 155, and the resonant frequency and the driving displacement characteristics according to the materials were compared when all other shapes were identical. The results are shown in Table 1 below.

TABLE 1

| | SUS316 | | C5210 | | C1720 | |
|---|---|---|---|---|---|---|
| Material | (Stainless Steel) | | (Phosphor Bronze) | | (Beryllium Copper) | |
| Density | 7.98e−06 | kg/mm³ | 8.8e−06 | kg/mm³ | 8.36e−06 | kg/mm³ |
| Young's Modulus | 1.93e+05 | Mpa | 1.1e+05 | Mpa | 1.275e+05 | Mpa |
| Resonant Frequency | 394 | kHz | 332 | kHz | 348 | kHz |
| Displacement | 1398 | nm | 1883 | nm | 1752 | nm |

Referring to Table 1, different results in the resonant frequency and the driving displacement were observed for the bracket 155 made of different materials but having the same shape. Particularly, when the bracket 155 was made of phosphor bronze (C5210), which has a high density and a low elastic modulus, was the bracket 155 had the lowest resonant frequency and the largest driving displacement.

Through these simulation results, it may be confirmed that using a metal with a high density and a low Young's Modulus as the material for the bracket 155 is advantageous for improving the driving characteristics of the piezoelectric actuator 150.

### Simulation 4

To evaluate the driving stability of the piezoelectric actuator 150 shown in FIG. 8, a frequency analysis by resonant mode was performed. The results are shown in Table 2 below.

TABLE 2

| Resonant Modes by Frequency | |
|---|---|
| Y-axis Bending | 211 kHz |
| 1st X-axis Bending | 257 kHz |
| Longitudinal | 332 kHz |
| 2nd X-axis Bending | 425 kHz |

Referring to Table 2, the frequency of each resonant mode occurring in the piezoelectric actuator 150 is shown. This frequency analysis by mode is intended to identify interference between different resonant modes, as overlapping between modes may cause malfunction and noise of the piezoelectric actuator 150.

Specifically, it was confirmed that the longitudinal mode, which represents the length-direction vibration of the driving rod 157, occurs at 332 kHz. Looking at the resonant modes occurring before and after this longitudinal mode, the 1st x-axis bending mode occurs at 257 kHz, and the 2nd x-axis bending mode occurs at 425 kHz.

This frequency distribution indicates that sufficient frequency intervals have been secured between the target driving mode, which is the longitudinal mode, and adjacent modes. Specifically, there is a gap of 75 kHz between the longitudinal mode (332 kHz) and the 1st x-axis bending mode (257 kHz), and a gap of 93 kHz between the longitudinal mode (332 kHz) and the 2nd x-axis bending mode (425 kHz). By securing such sufficient frequency intervals, stable driving of the piezoelectric actuator 150 may be possible.

### Simulation 5

Referring to Table 3 below, the results of comparing the piezoelectric actuator 150 shown in FIG. 8 according to the embodiment and a comparative example of a piezoelectric actuator may be confirmed. The length of the driving rod 157 was compared under the same conditions. The comparative example of the piezoelectric actuator has a structure in which a rectangular parallelepiped-shaped piezoelectric element, formed by stacking multiple ceramic substrates, is at the center, with a driving rod at the top and a weight at the bottom.

TABLE 3

| | Comparative Example | | Embodiment | |
|---|---|---|---|---|
| Total Size | 2 × 0.5 × 2.9 | mm | 0.9 × 0.5 × 2.8 | mm |
| Piezoelectric | 1 × 1 × 0.7 | mm | 1 × 1 × 0.5 | mm |
| Element Size | | | | |
| Capacitance | 33 | nF | 23 | nF |
| Resonant | 435 | kHz | 332 | kHz |
| Frequency | | | | |
| Displacement | 1408 | nm | 1883 | nm |
| Resonant Modes | X-bending | 243 kHz | Y-bending | 211 kHz |
| by Frequency | Y-bending | 323 kHz | 1st X-bending | 257 kHz |
| | 1st Torsion | 413 kHz | Longitudinal | 332 kHz |
| | Longitudinal | 435 kHz | 2nd X-bending | 425 kHz |
| | 2nd Torsion | 526 kHz | | |

As a result of the simulation, the piezoelectric actuator 150 according to this embodiment may have the following advantages compared to the comparative example of the piezoelectric actuator. Specifically, the overall size and height may be reduced, and the capacitance may be reduced. Also, as the resonant frequency decreases, the driving displacement increases.

In particular, in terms of interference between resonant modes, the comparative example of the piezoelectric actuator has a relatively small gap of 22 kHz between the frequency of the 1st torsion mode (413 kHz) and the frequency of the longitudinal mode (435 kHz), posing a risk of interference between these modes. On the other hand, the piezoelectric actuator 150 according to this embodiment, as explained earlier, has sufficient frequency intervals secured between adjacent resonant modes, minimizing the risk of interference between modes.

As such, the piezoelectric actuator 150 according to this embodiment has a simplified structure, an improved performance, and a more stable driving capability compared to the comparative example.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed to have a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A camera module comprising:
a housing having an internal space;
a carrier disposed in the internal space of the housing and accommodating a lens barrel having a lens mounted therein; and
a piezoelectric actuator disposed in the housing, supporting the carrier, and configured to apply a driving force to the carrier in an optical axis direction,
wherein the piezoelectric actuator comprises:
a driving rod extending in the optical axis direction and supporting the carrier;
a bracket comprising an upper frame comprising a supporting surface supporting one end of the driving rod, a lower frame comprising at least a pair of holding surfaces facing each other in a direction crossing the supporting surface and spaced apart from each other, and a middle frame connecting the upper frame and the lower frame to each other; and
a piezoelectric element fixed between the pair of holding surfaces and spaced apart from the upper frame.

2. The camera module of claim 1, wherein one side surface of the driving rod contacts one corner of the carrier.

3. The camera module of claim 1, further comprising:
a carrier preload spring fixed to the carrier; and
a housing preload spring fixed to the housing,
wherein the driving rod is interposed between the carrier preload spring and the housing preload spring so that the driving rod is pressed between the carrier preload spring and the housing preload spring.

4. The camera module of claim 3, wherein a portion of the carrier preload spring is inserted into the carrier, and another portion of the carrier preload spring protrudes from the carrier and contacts the driving rod.

5. The camera module of claim 3, wherein opposite ends of the housing preload spring are fixed to adjacent side walls of the housing, and a middle portion of the housing preload spring contacts the driving rod.

6. The camera module of claim 1, wherein the bracket is fixed to the housing.

7. The camera module of claim 1, further comprising a rolling member disposed between the carrier and the housing,
wherein the driving rod and the rolling member are disposed at opposite corners of the carrier.

8. The camera module of claim 1, wherein the piezoelectric element is fixed in contact with the holding surfaces of the lower frame of the bracket.

9. The camera module of claim 1, wherein a cavity is formed between the piezoelectric element and the upper frame as a result of the piezoelectric element being spaced apart from the upper frame.

10. The camera module of claim 1, wherein the middle frame extends downward from opposite edges of the upper frame.

11. The camera module of claim 1, wherein the middle frame comprises an inclined surface extending from the upper frame and connecting to the lower frame.

12. The camera module of claim 1, wherein a width of the piezoelectric element is greater than a cross-sectional diameter of the driving rod.

13. The camera module of claim 1, wherein the middle frame comprises a first bracket hole formed as a through opening in the middle frame.

14. The camera module of claim 1, wherein the lower frame comprises a second bracket hole formed as a through opening in the lower frame.

15. A piezoelectric actuator comprising:
a driving rod extending in one direction;
a bracket comprising an upper frame comprising a supporting surface supporting one end of the driving rod, a lower frame comprising at least a pair of holding surfaces facing each other in a direction crossing the supporting surface and spaced apart from each other, and a middle frame connecting the upper frame and the lower frame to each other; and
a piezoelectric element fixed between the pair of holding surfaces of the lower frame of the brackets and spaced apart from the upper frame.

16. The piezoelectric actuator of claim 15, wherein the piezoelectric element is fixed in contact with the holding surfaces of the lower frame of the brackets.

17. The piezoelectric actuator of claim 15, wherein a cavity is formed between the piezoelectric element and the upper frame as a result of the piezoelectric element being spaced apart from the upper frame.

18. The piezoelectric actuator of claim 15, wherein the middle frame extends downward from opposite edges of the upper frame.

19. The piezoelectric actuator of claim 15, wherein the middle frame comprises an inclined surface extending from the upper frame and connecting to the lower frame.

20. The piezoelectric actuator of claim 15, wherein a width of the piezoelectric element is greater than a cross-sectional diameter of the driving rod.

21. The piezoelectric actuator of claim 15, wherein the middle frame comprises a first bracket hole formed as a through opening in the middle frame.

22. The piezoelectric actuator of claim 15, wherein the lower frame comprises a second bracket hole formed as a through opening in the lower frame.

23. A piezoelectric actuator comprising:
a driving rod;
a bracket comprising a supporting surface supporting one end of the driving rod so that the driving rod extends in a direction perpendicular to the mounting surface, and a pair of holding surfaces facing each other in a direction parallel to the supporting surface; and
a piezoelectric element fixed between the pair of holding surfaces,
wherein the piezoelectric element is configured to bend away from the supporting surface in response to a voltage having a first polarity applied to the piezoelectric element, and bend toward the supporting surface in response to a voltage having a second polarity opposite to the first polarity applied to the piezoelectric element, and
the mounting bracket is configured to be deformed by the piezoelectric element bending away from the supporting surface so that the supporting surface moves away from the piezoelectric element, thereby moving the driving rod in a first direction, and be deformed by the piezoelectric element bending toward the supporting surface so that the supporting surface moves toward the piezoelectric element, thereby moving the driving rod in a second direction opposite to the first direction.

24. The piezoelectric actuator of claim 23, wherein the mounting bracket comprises:
an upper frame comprising the supporting surface;
a lower frame comprising the pair of holding surfaces; and
a middle frame connecting the upper frame and the lower frame to each other.

25. The piezoelectric actuator of claim 24, wherein a width of the lower frame in the direction parallel to the supporting surface is greater than a width of the upper frame in the direction parallel to the supporting surface, and
a width of the middle frame in the direction parallel to the supporting surface increases from the upper frame toward the lower frame.

26. The piezoelectric actuator of claim 24, wherein the middle frame includes a bracket hole formed as a through opening in the middle frame and extending in the direction parallel to the supporting surface.
